(19) United States
(12) Patent Application Publication
(10) Pub. No.: US 2024/0147782 A1
(43) Pub. Date: May 2, 2024

(54) DISPLAY PANEL, METHOD FOR MANUFACTURING THE SAME, AND DISPLAY APPARATUS

(71) Applicant: Shanghai Tianma Micro-Electronics Co., Ltd., Shanghai (CN)

(72) Inventor: Quanpeng YU, Shanghai (CN)

(73) Assignee: Shanghai Tianma Micro-Electronics Co., Ltd., Shanghai (CN)

(21) Appl. No.: 18/407,206

(22) Filed: Jan. 8, 2024

(30) Foreign Application Priority Data
Jul. 3, 2023 (CN) 202310808586.3

(51) Int. Cl. H10K 59/126; H10K 59/12

(52) U.S. Cl. CPC H10K 59/126; H10K 59/1201

(57) ABSTRACT

A display panel includes a substrate and a first display region. The first display region includes: a light transmission region, a first blocking portion located at a side of the substrate, a second blocking portion located at a side of the first blocking portion away from the substrate, and a first conductive layer located at a side of the second blocking portion away from the first blocking portion. The first conductive layer includes a first hollowed portion and a first non-hollowed portion. The first hollowed portion is located in the light transmission region. Along a first direction, the first blocking portion at least partially overlaps with the second blocking portion, and an overlapping location between the first blocking portion and the second blocking portion at least partially overlaps with the first non-hollowed portion. The first direction is perpendicular to a plane of the substrate.

### CROSS-REFERENCE TO RELATED APPLICATION

The present disclosure claims priority to Chinese Patent Application No. 202310808586.3, filed on Jul. 3, 2023, the content of which is incorporated herein by reference in its entirety.

### TECHNICAL FIELD

The present disclosure relates to the field of display technologies, and in particular, to a display panel, a method for manufacturing the display panel, and a display apparatus.

### BACKGROUND

With the continuous development of display technologies, consumers' requirements for display screens continue to increase. At present, various display screens such as liquid crystal display screens and organic light-emitting display screens have been developed rapidly.

At present, in order to increase a screen-to-body ratio of a display panel, photosensitive components such as a camera are disposed in a display region. Improving the light transmittance of the region disposed with the photosensitive components has become a research focus in the industry.

### SUMMARY

Embodiments of the present disclosure provide a display panel, a method for manufacturing the display panel, and a display apparatus.

One aspect of the present disclosure provides a display panel. The display panel includes a substrate including a first display region. The first display region includes: a light transmission region, a first blocking portion located at a side of the substrate, a second blocking portion located at a side of the first blocking portion away from the substrate, and a first conductive layer located at a side of the second blocking portion away from the first blocking portion. The first conductive layer includes a first hollowed portion and a first non-hollowed portion, and the first hollowed portion is located in the light transmission region. Along a first direction, the first blocking portion at least partially overlaps with the second blocking portion. An overlapping between the first blocking portion and the second blocking portion at least partially overlaps with the first non-hollowed portion. The first direction is perpendicular to a plane of the substrate.

Another aspect of the present disclosure provides a method for manufacturing a display panel. The method includes: providing a substrate including a first display region; forming a first blocking portion at a side of the substrate, where the first blocking portion is at least located in the first display region; forming a second blocking portion at a side of the first blocking portion away from the substrate, where the second blocking portion is at least located in the first display region; and the second blocking portion at least partially overlaps with the first blocking portion in a first direction perpendicular to the plane of the substrate; forming an initial conductive layer at a side of the second blocking portion away from the first blocking portion, where the initial conductive layer is at least located in the first display region, the first display region includes a first region and a second region, and the second region at least partially overlaps with an overlapping portion of the second blocking portion and the first blocking portion along the first direction; and etching the initial conductive layer by laser rays to remove at least a portion of the initial conductive layer located in the first region to form a first conductive layer. The first conductive layer includes a first hollowed portion at least partially located in the first region and a non-hollowed portion at least partially located in the second region, so that the overlapping portion of the first blocking portion and the second blocking portion at least partially overlaps with the first non-hollowed portion.

Yet another aspect of the present disclosure provides a display apparatus. The display apparatus includes a display panel. The display panel includes a substrate including a first display region. The first display region includes: a light transmission region, a first blocking portion located at a side of the substrate, a second blocking portion located at a side of the first blocking portion away from the substrate, and a first conductive layer located at a side of the second blocking portion away from the first blocking portion. The first conductive layer includes a first hollowed portion and a first non-hollowed portion, and the first hollowed portion is located in the light transmission region. Along a first direction, the first blocking portion at least partially overlaps with the second blocking portion. An overlapping between the first blocking portion and the second blocking portion at least partially overlaps with the first non-hollowed portion. The first direction is perpendicular to a plane of the substrate.

### DRAWINGS

In order to more clearly illustrate technical solutions of embodiments of the present disclosure, the accompanying drawings used in the embodiments are briefly described below. The drawings described below are merely a part of the embodiments of the present disclosure. Based on these drawings, those skilled in the art can obtain other drawings.

FIG. 1 is a top view of a display panel according to an embodiment of the present disclosure;

FIG. 2 is an enlarged schematic diagram of a region Q1 in FIG. 1;

FIG. 3 is an enlarged schematic diagram of a region Q2 in FIG. 2;

FIG. 4 is a cross-sectional view taken along line BB′ in FIG. 3;

FIG. 5 is a top view of a shielding layer in the region Q1 in FIG. 1;

FIG. 6 is an equivalent circuit diagram of a sub-pixel according to an embodiment of the present disclosure;

FIG. 7 is a cross-sectional view of a second display region according to an embodiment of the present disclosure;

FIG. 8 is a display panel according to an embodiment of the present disclosure;

FIG. 9 is a cross-sectional view taken along line CC′ in FIG. 8;

FIG. 10 is a partial enlarged diagram of a first display region of a display panel according to another embodiment of the present disclosure;

FIG. 11 is a partial enlarged diagram of a display panel according to another embodiment of the present disclosure;

FIG. 12 is a cross-sectional view taken along line DD′ of FIG. 11;

FIG. 13 is a partial enlarged diagram of a display panel according to another embodiment of the present disclosure;

FIG. 14 is a cross-sectional diagram of a display panel according to another embodiment of the present disclosure;

FIG. 15 is a partial enlarged diagram of a display panel according to another embodiment of the present disclosure;

FIG. 16 is a schematic diagram of a first conductive layer in FIG. 15;

FIG. 17 is a partial enlarged diagram of a display panel according to another embodiment of the present disclosure;

FIG. 18 is a cross-sectional view taken along line EE′ in FIG. 17;

FIG. 19 is a partial enlarged diagram of a display panel according to another embodiment of the present disclosure;

FIG. 20 is a partial enlarged diagram of a first display region of a display panel according to another embodiment of the present disclosure;

FIG. 21 is an enlarged diagram of a region Q1 in FIG. 1;

FIG. 22 is a schematic diagram of a display apparatus according to an embodiment of the present disclosure; and

FIG. 23 is a cross-sectional view taken along line FF′ in FIG. 22.

### DESCRIPTION OF EMBODIMENTS

In order to better understand technical solutions of the present disclosure, the embodiments of the present disclosure are described in details with reference to the drawings.

It should be clear that the described embodiments are merely part of the embodiments of the present disclosure rather than all of the embodiments. All other embodiments obtained by those skilled in the art without paying creative labor shall fall into the protection scope of the present disclosure.

The terms used in the embodiments of the present disclosure are merely for the purpose of describing specific embodiment, rather than limiting the present disclosure. The terms “a”, “an”, “the” and “said” in a singular form in the embodiments of the present disclosure and the attached claims are also intended to include plural forms thereof, unless noted otherwise.

It should be understood that the term “and/or” used in the context of the present disclosure is to describe a correlation relation of related objects, indicating that there may be three relations, e.g., A and/or B may indicate only A, both A and B, and only B. In addition, the symbol “/” in the context generally indicates that the relation between the objects in front and at the back of “!” is an “or” relationship.

It should be understood that although the terms ‘first’, ‘second’ and ‘third’ are used in the present disclosure to describe conductive portions, these conductive portions should not be limited to these terms. These terms are used only to distinguish the conductive portions from each other. For example, without departing from the scope of the embodiments of the present disclosure, a first conductive portion may also be referred to as a second conductive portion. Similarly, the second conductive portion may also be referred to as the first conductive portion.

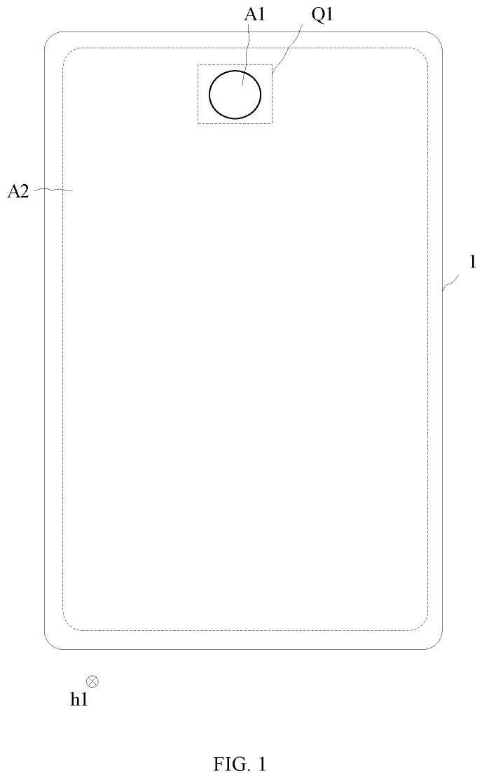

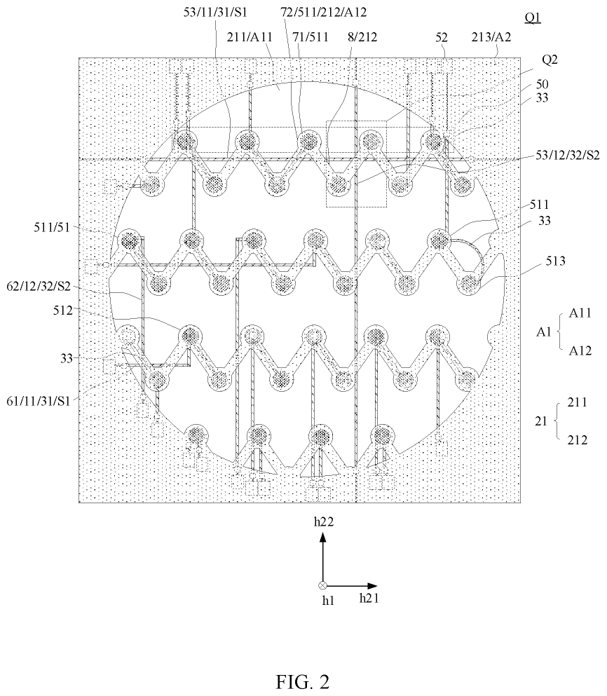

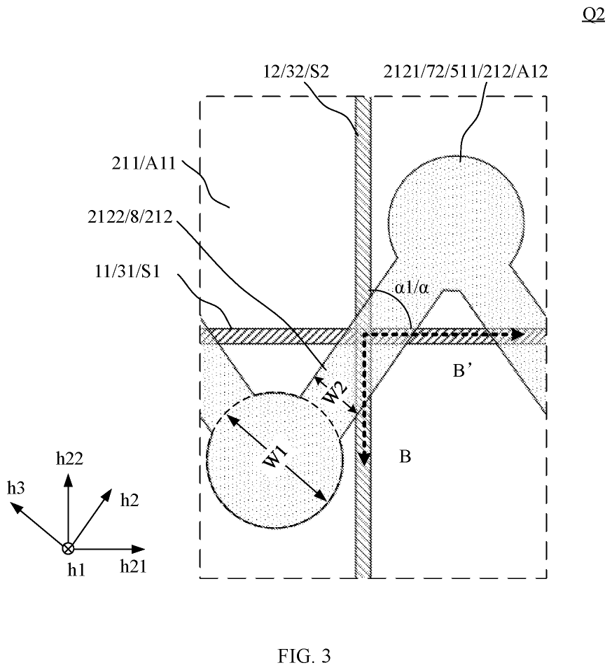

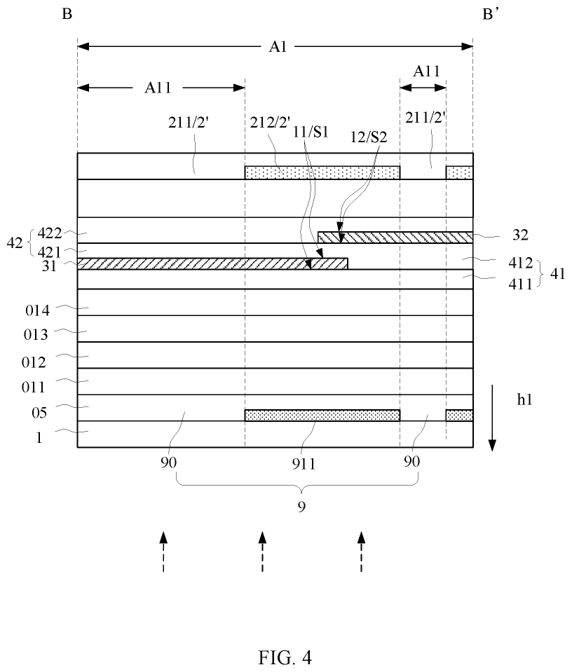

Embodiments of the present disclosure provide a display panel. FIG. 1 is a top view of a display panel according to an embodiment of the present disclosure, FIG. 2 is an enlarged schematic diagram of a region Q1 in FIG. 1, FIG. 3 is an enlarged schematic diagram of a region Q2 in FIG. 2, and FIG. 4 is a cross-sectional view taken along line BB′ in FIG. 3. As shown in FIG. 1 to FIG. 4, the display panel includes a substrate 1. The substrate 1 may be a transparent substrate such as a glass substrate. The substrate 1 includes a first display region A1 and a second display region A2. For example, the second display region A2 may at least partially surround the first display region A1. In some embodiments of the present disclosure, a light transmittance of the first display region A1 is greater than that of the second display region A2. As shown in FIG. 2, the first display region A1 includes a light transmission region A11 and a light-emitting region A12. The light-emitting region A12 includes light-emitting elements so that the first display region A1 can have display function while having a high light transmittance.

As shown in FIG. 2, FIG. 3 and FIG. 4, the first display region A1 further includes: a first blocking portion 11, a second blocking portion 12, and a first conductive layer 21. The first blocking portion 11 is located at a side of substrate 1. The second blocking portion 12 is located at a side of the first blocking portion 11 away from the substrate 1. The first conductive layer 21 is located at a side of the second blocking portion 12 away from the first blocking portion 11. Along a first direction h1, the first blocking portion 11 at least partially overlaps with the second blocking portion 12. The first direction h1 is perpendicular to a plane of substrate 1.

As shown in FIG. 2 and FIG. 3, the first conductive layer 21 includes a first hollowed portion 211 and a first non-hollowed portion 212. The first hollowed portion 211 and the first non-hollowed portion 212 are located in the first display region A1. For example, at least part of the first hollowed portion 211 is located in the light transmission region A11, and the light transmittance of the first hollowed portion 211 is high, which can improve the light transmittance of the first display region A1. At least part of the first non-hollowed portion 212 is located in the light-emitting region A12.

As shown in FIG. 2, the first conductive layer 21 further includes a second non-hollowed portion 213 located in the second display region A2. In some embodiments, in the second display region A2, the hollowed portion is not provided in the first conductive layer 21, that is, the first conductive layer 21 is a planar structure in the entire second display region A2. For example, the first non-hollowed portion 212 can be electrically connected to the second non-hollowed portion 213.

As shown in FIG. 2, FIG. 3 and FIG. 4, along the first direction h1, an overlapping portion of the first blocking portion 11 and the second blocking portion 12 at least partially overlaps with the first non-hollowed portion 212.

For example, in the manufacturing of the display panel, a first blocking portion 11, a second blocking portion 12, and a first conductive layer 21 are formed sequentially at a side of substrate 1. When the first conductive layer 21 having the first hollowed portion 211 is formed, an initial conductive layer 2′ with an entire planar structure can be firstly formed through a film forming process. The entire planar structure refers to a situation where an orthographic projection of the initial conductive layer 2′ on a plane of substrate 1 covers the first display region A1 and the second display region A2. In other words, the initial conductive layer 2′ does not have a hollowed portion. After the initial conductive layer 2′ is formed, the portion corresponding to the light transmission region A11 in the initial conductive layer 2′ can be removed by a patterning process to form the first conductive layer 21, and thus the first conductive layer 21 including the first hollowed portion 211 corresponding to the light transmission region A11 is formed. In some embodiments of the present disclosure, the patterning process includes a lithography process. For example, in the embodiments of the present disclosure, the initial conductive layer 2′ is irradiated by laser rays, that is, the initial conductive layer 2′ is subjected to exposure so that the portion corresponding to the light transmission region A11 in the initial conductive layer 2′ receives laser rays and is removed under the action of laser rays. A region outside the light transmission region A11 in the initial conductive layer 2′, e.g., a portion corresponding to the light-emitting region A12, does not receive laser rays and is remained in the subsequent processes, thereby forming the first conductive layer 21 that has the first hollowed portion 211 and the first non-hollowed portion 212. In FIG. 4, the laser ray is represented by a dashed line with an arrow. In some embodiments of the present disclosure, the laser ray can be emitted vertically towards the initial conductive layer 2′ from a side of the substrate 1 away from the initial conductive layer 2′. That is, the direction of the laser rays can be parallel to the first direction h1.

In some embodiments of the present disclosure, the transmittance of the first blocking portion 11 and the transmittance of the second blocking portion 12 for etching light is smaller than or equal to a first preset value, that is, the first blocking portion 11 and the second blocking portion 12 will reduce the energy of the laser ray passing through them. The first preset value can be set according to factors such as the material and thickness of the initial conductive layer 2′ and the energy of the etching light. Therefore, a large reduction in energy of the laser ray will occur after the laser ray passes through an overlapping portion of the first blocking portion 11 and the second blocking portion 12 in the first direction h1. In the embodiments of the present disclosure, the overlapping portion of the first blocking portion 11 and the second blocking portion 12 at least partially overlaps the first non-hollowed portion 212 in the first direction h1, that is, the overlapping portion of the first blocking portion 11 and the second blocking portion 12 is disposed by corresponding to the region to be remained in the initial conductive layer 2′. In this way, in the process of irradiating the initial conductive layer 2′ by laser ray to form the first conductive layer 21, the laser ray cannot pass through the overlapping portion of the first blocking portion 11 and the second blocking portion 12 to irradiate the portion corresponding to the light transmission region A11 in the initial conductive layer 2′. Therefore, it can avoid the situation that the laser ray with a large energy reduction after passing through the first blocking portion 11 and the second blocking portion 12 cannot completely etch the portion corresponding to the light transmission region A11 in the initial conductive layer 2′, and then it can avoid occurrence of the residual foreign matter in the light transmission region A11, which can improve the process yield. Moreover, the residual foreign matter will affect the light transmittance of the first conductive layer 21 in the light transmission region A11. Therefore, the configuration provided by the embodiments of the present disclosure can ensure that the first hollowed portion 211 in the first conductive layer 21 has a sufficiently high light transmittance, so as to ensure the operating performance of the photosensitive element corresponding to the first display region A1.

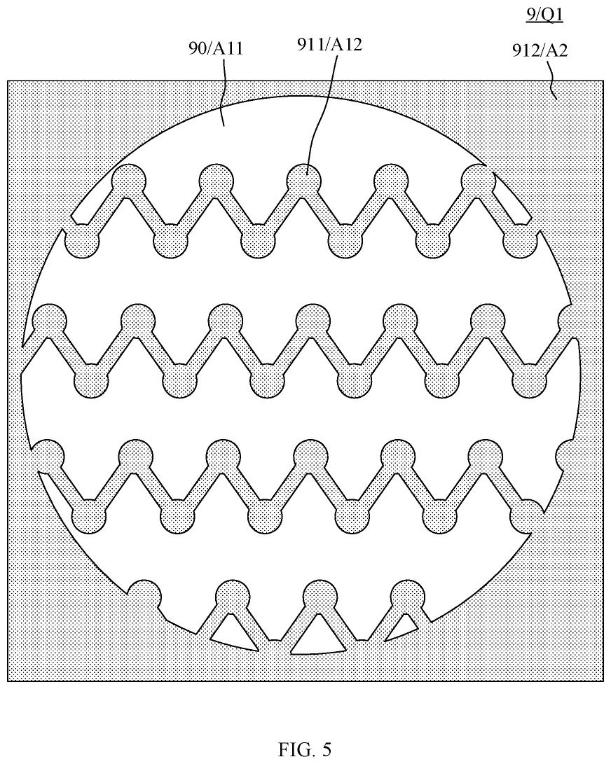

In some embodiments of the present disclosure, the display panel further includes a shielding layer. FIG. 5 is a top view of a shielding layer in the region Q1 in FIG. 1. As shown in FIG. 4 and FIG. 5, the shielding layer 9 includes a second hollowed portion 90 and a third non-hollowed portion 911. At least part of the second hollowed portion 90 is located in the light transmission region A11, and at least part of the third non-hollowed portion 911 is located in the light-emitting region A12. The shielding layer 9 is located at a side of the first blocking portion 11 close to the substrate 1. Along the first direction h1, the second hollowed portion 90 at least partially overlaps the first hollowed portion 211, and the third non-hollowed portion 911 at least partially overlaps with the first non-hollowed portion 212. The non-hollowed portions of the shielding layer 9, including the third non-hollowed portion 911, correspond to regions of the display panel that do not need to be removed by laser ray, such as regions for light-emitting elements, circuits and wiring. The second hollowed portion 90 corresponds to the above light transmission region A1, that is, the second hollowed portion 90 corresponds to the region in the display panel that needs to be removed by laser. In the process of irradiating the initial conductive layer 2′ by laser to form the first conductive layer 21, the laser ray can pass through the second hollowed portion 90 without passing through the non-hollowed portion in the shielding layer 9 such as the third non-hollowed portion 911. In the first direction h1, the overlapping portion of the first blocking portion 11 and the second blocking portion 12 at least partially overlaps with the third non-hollowed portion 911 in the shielding layer 9. Therefore, the overlapping portion of the first blocking portion 11 and the second blocking portion 12 will not be irradiated by laser ray, and the laser ray beam will not pass through the overlapping portion of the first blocking portion 11 and the second blocking portion 12 to irradiate the portion corresponding to the light transmission region A11 in the initial conductive layer 2′. Therefore, it can avoid the problem that the laser ray passing through the first blocking portion 11 and the second blocking portion 12 has a larger energy attenuation and cannot completely etch the portion corresponding to the light transmission region A11 in the initial conductive layer 2′, and then avoid occurrence of residual foreign matter in the light transmission region A11.

In some embodiments of the present disclosure, as shown in FIG. 2 and FIG. 5, the shape and area of the second hollowed portion 90 can be approximately the same as the shape and area of the light transmission region A11 of the display panel.

In some embodiments, as shown in FIG. 2 and FIG. 3, the first display region A1 includes a first conductive portion 31 and a second conductive portion 32. In some embodiments, the first conductive portion 31 and the second conductive portion 32 are configured to transmit one or more signals required for display of first display region A1 and/or the second display region A2.

Referring to FIG. 4, the display panel further includes a first insulation layer 41 located at a side of the first conductive portion 31 and a second insulation layer 42 located at a side of the second conductive portion 32. The first blocking portion 11 includes a first interface S1 between the first insulation layer 41 and the first conductive portion 31. The second blocking portion 12 includes a second interface S2 between the second insulation layer 42 and the second conductive portion 32. That is, along the first direction h1, the overlapping portion of the first interface S1 and the second interface S2 at least partially overlaps with the first non-hollowed portion 212. The materials of the first insulation layer 41 and the first conductive portion 31 are different, so that the etching light, such as laser ray, will attenuate when passing through the first interface S1 between the first insulation layer 41 and the first conductive portion 31. Similarly, the materials of the second insulation layer 42 and the second conductive portion 32 are different, so that the etching light will attenuate when passing through the second interface S2 between the second insulation layer 42 and the second conductive portion 32. Along the first direction h1, the embodiments of the present disclosure set the overlapping portion of the first interface S1 and the second interface S2 to at least partially overlap with the first non-hollowed portion 212, so that in the process of irradiating the initial conductive layer 2′ by laser ray to form the first conductive layer 21, the laser ray beam will not pass through the overlapping portion of the first interface S1 and the second interface S2 to irradiate the portion corresponding to the light transmission region A11 in the initial conductive layer 2′. Therefore, use of the inventive technology can avoid the problem where the laser ray with more energy attenuation after passing through the first interface S1 and the second interface S2 cannot completely etch the portion corresponding to the light transmission region A11 in the initial conductive layer 2′. Therefore, occurrence of residual foreign matter in the light transmission region A11 can be avoided. In this way, influence of the interface structures corresponding to the first conductive portion 31 and the second conductive portion 32 can be avoided with respect to the light transmittance of the first hollowed portion 211 in the first conductive layer 21 without affecting the electrical signal transmitting of the first conductive portion 31 and the second conductive portion 32.

In some embodiments of the present disclosure, as shown in FIG. 2, FIG. 3, and FIG. 4, the first conductive portion 31 at least partially overlaps the second conductive portion 32 along the first direction h1.

As shown in FIG. 4, an orthographic projection of the first insulation layer 41 on the plane of substrate 1 covers the orthographic projection of the first conductive portion 31 on the plane of substrate 1. The orthographic projection of the second insulation layer 42 on the plane of substrate 1 covers the orthographic projection of the second conductive portion 32 on the plane of substrate 1. In some embodiments of the present disclosure, the first interface S1 is a surface on which the first conductive portion 31 contacts the first insulation layer 41. The second interface S2 is a surface on which the second conductive portion 32 contacts the second insulation layer 42.

As shown in FIG. 2 and FIG. 3, the extension direction of the first interface S1 intersects the extension direction of the second interface S2. In FIG. 2 and FIG. 3, the first conductive portion 31 extends along the fourth direction h21, and the second conductive portion 32 extends along the fifth direction h22, that is, the first interface S1 extends along the fourth direction h21, and the second interface S2 extends along the fifth direction h22. Both the fourth direction h21 and the fifth direction h22 are perpendicular to the first direction h1.

In the embodiments of the present disclosure, the first insulation layer 41 includes first and second insulation sub-layers that are stacked. The first and second insulation sub-layers may be located on two sides of the first conductive portion 31 along the first direction h1, and/or, the second insulation layer 42 includes third and fourth insulation sub-layers that are stacked. The third and fourth insulation sub-layers may be located on two sides of second conductive portion 32 along the first direction h1. FIG. 4 schematically shows that the first insulation layer 41 includes the first insulation sub-layer 411 and the second insulation sub-layer 412, and the second insulation layer 42 includes the third insulation sub-layer 421 and the fourth insulation sub-layer 422. The first insulation sub-layer 411 can insulate the first conductive portion 31 from other conductive structures located at a side of the first conductive portion 31 close to the substrate 1. The second insulation sub-layer 412 can insulate the first conductive portion 31 from other conductive structures such as the second conductive portion 32 located at a side of the first conductive portion 31 away from the substrate 1. The third insulation sub-layer 421 can insulate the second conductive portion 32 from other conductive structures such as the first conductive portion 31 located at a side of the second conductive portion 32 close to the substrate 1. The fourth insulation sub-layer 422 can insulate the second conductive portion 32 from other conductive structures located at a side of the second conductive portion 32 away from the substrate 1.

It should be noted that when only one insulation layer is located between the first conductive portion 31 and the second conductive portion 32, this insulation layer may be referred to as either the second insulation sub-layer 412 or the third insulation sub-layer 421.

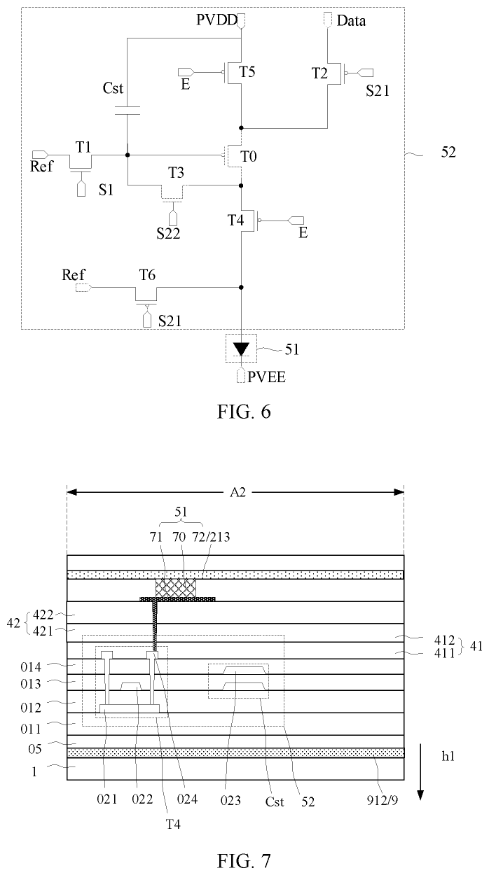

In some embodiments of the present disclosure, the display panel includes multiple sub-pixels. FIG. 6 is an equivalent circuit diagram of a sub-pixel. In some embodiments of the present disclosure, as shown in FIG. 6, the sub-pixel includes a light-emitting element 51 and a pixel drive circuit 52 that are electrically connected. The pixel drive circuit 52 is configured to drive the light-emitting element 51 to emit light. FIG. 6 schematically shows that the pixel drive circuit 11 includes a storage capacitor Cst, a drive transistor T0, a first transistor T1, a second transistor T2, a third transistor T3, a fourth transistor T5 and a sixth transistor T6.

In some embodiments of the present disclosure, the display panel further includes a data line Data, a first power line PVDD, a reset signal line Ref, a first scan line S1, a second scan line S2, and a light-emitting control signal line E. The data line Data is electrically connected to a source electrode or a drain electrode of the second transistor T2. The first scan line S1 is electrically connected to a gate electrode of the first transistor T1. The second scan line S2 is electrically connected to a gate electrode of the second transistor T2, a gate electrode of the third transistor T3, and a gate electrode of the sixth transistor T6. The light-emitting control signal line E is electrically connected to gate electrodes of the fourth transistor T4 and the sixth transistor T6. The first power line PVDD is electrically connected to a source electrode or a drain electrode of the fifth transistor T5. The reset signal line Ref is electrically connected to the first transistor T1 and the sixth transistor T6.

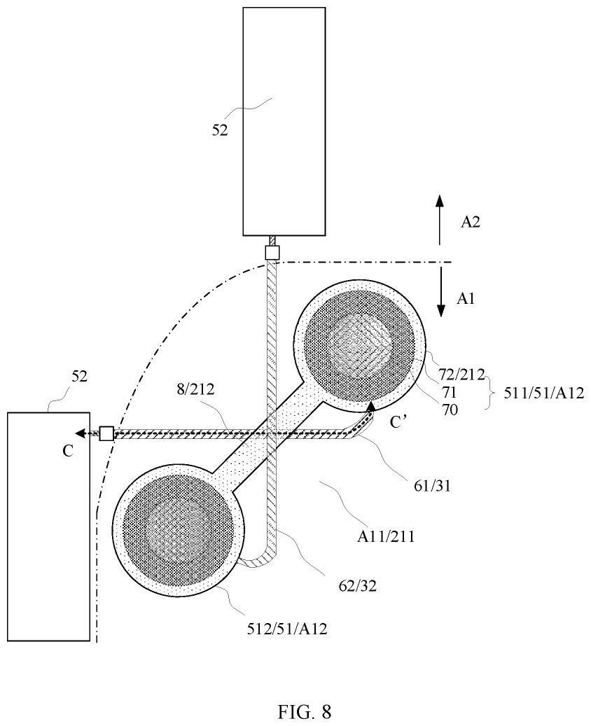

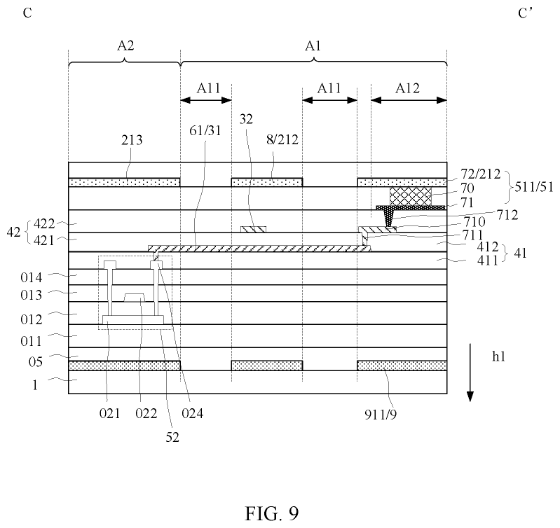

FIG. 7 is a cross-sectional view of a second display region according to an embodiment of the present disclosure, FIG. 8 is a partial enlarged view of a display panel according to an embodiment of the present disclosure, and FIG. 9 is a cross-sectional view taken along line CC′ in FIG. 8. Referring to FIG. 7, FIG. 8, and FIG. 9, the light-emitting element 51 includes a first electrode 71, a light-emitting layer 70, and a second electrode 72 that are stacked. In some embodiments of the present disclosure, the first electrode 71 is located at a side of the light-emitting layer 70 close to the substrate 1, and the second electrode 72 is located at a side of the light-emitting layer 70 away from the substrate 1. In some embodiments of the present disclosure, one of the first electrode 71 and the second electrode 72 includes an anode, and the other includes a cathode. Unless otherwise specified below, the first electrode 71 includes an anode, and the second electrode 72 includes a cathode. When the display panel is used to display, the pixel drive circuit 52 provides an anode drive signal to the first electrode 71 of the light-emitting element 51, and the second electrode 72 of the light-emitting element 51 receives the second supply voltage PVEE.

In some embodiments of the present disclosure, as shown in FIG. 2, FIG. 3, and FIG. 8, multiple light-emitting elements 51 at least include a first light-emitting element 511 located in the first display region A1. In some embodiments of the present disclosure, at least part of the first light-emitting element 511 is located in the light-emitting region A12.

Referring to FIG. 4, FIG. 7 and FIG. 9, the display panel further includes a first array insulation layer 011, a first semiconductor layer 021, a second array insulation layer 012, a first metal layer 022, a third array insulation layer 013, a second metal layer 023, a fourth array insulation layer 014, a third metal layer 024 and a fifth array insulation layer 05. The first metal layer 022 includes a gate electrode of at least one transistor in the pixel drive circuit 52 and one plate of a storage capacitor Cst, and the second metal layer 023 includes the other plate of the storage capacitor Cst. The third metal layer 024 includes a source electrode and a drain electrode of at least one transistor in the pixel drive circuit 52. The first semiconductor layer 021 includes a channel of at least one transistor in the pixel drive circuit 52.

Referring to FIG. 7, the shielding layer 9 further includes a fourth non-hollowed portion 912 located in the second display region A2. Along the first direction h1, the fourth non-hollowed portion 912 at least partially overlaps with the second non-hollowed portion 213.

In some embodiments of the present disclosure, the first non-hollowed portion 212 can include the second electrode 72 of the first light-emitting element 511.

In some embodiments of the present disclosure, as shown in FIG. 2, FIG. 3, and FIG. 8, the first non-hollowed portion 212 further includes an electrode connecting portion 8 by which two adjacent second electrodes 72 are electrically connected. In some embodiments, the electrode connecting portion 8 and the second electrode 72 in the first display region A1 are electrically connected to the second electrode 72 in the second display region A2 to reduce a voltage drop of the second supply voltage PVEE during transmission.

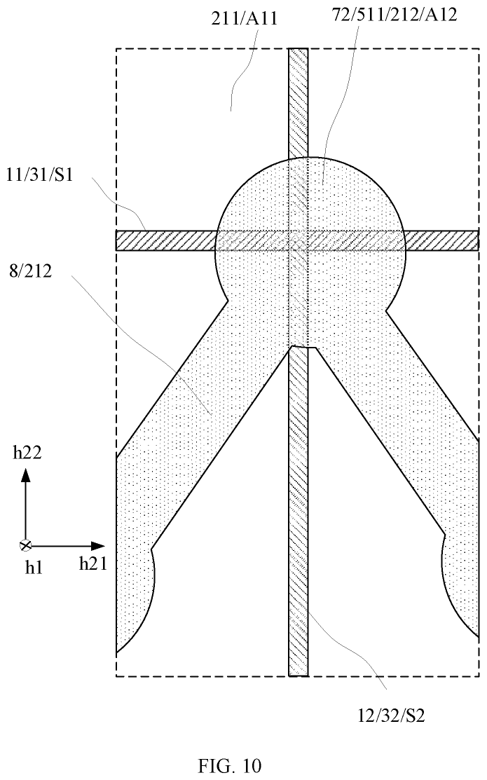

In some embodiments of the present disclosure, as shown in FIG. 2, FIG. 3, and FIG. 8, the overlapping portion of the first blocking portion 11 and the second blocking portion 12 may overlap with the electrode connecting portion 8 along the first direction h1. FIG. 10 is a partial enlarged diagram of a first display region of a display panel according to another embodiment of the present disclosure. Alternatively, as shown in FIG. 10, the overlapping portion of the first blocking portion 11 and the second blocking portion 12 may overlap with the second electrode 72.

It should be noted that FIG. 2 just schematically shows that the shape and arrangement law of the first hollowed portion 211 and the first non-hollowed portion 212 in the first conductive layer 21. The embodiments of the present disclosure can adjust the shape and/or arrangement law of the first hollowed portion 211 and the first non-hollowed portion 212 according to the different arrangements of the first light-emitting element 511 in the first display region A1.

As shown in FIG. 2, in the first display region A1, multiple light-emitting elements 51 are arranged along the fourth direction h21 into a light-emitting element row 50. Multiple light-emitting element rows 50 are arranged along the fifth direction h22. In embodiment of the present disclosure, the electrode connecting portion 8 can electrically connect the second electrodes 72 of two light-emitting elements 51 which are closest in two adjacent light-emitting element rows 50. In this way, while ensuring that any one of multiple second electrodes 72 located in the first display region A1 can receive corresponding signals, a total length of the electrode connecting portion 8 can be reduced, improving the light transmittance of the first display region A1.

In some embodiments of the present disclosure, as shown in FIG. 2 and FIG. 8, multiple light-emitting elements 51 at least include a first light-emitting element 511 and a second light-emitting element 512 that are located in the first display region A1. The first light-emitting element 511 is electrically connected to the corresponding pixel drive circuit 52 by a first connection line 61. The first connection line 61 includes the first conductive portion 31. The second light-emitting element 512 is electrically connected to the corresponding pixel drive circuit 52 by a second connection line 62. The second connection line 6 includes the second conductive portion 32. Namely, in some embodiments of the present disclosure, the first connection line 61 including the first conductive portion 31 and the second connection line 62 including the second conductive portion 32 can transmit the drive signals required by the first electrodes 71 of the first light-emitting element 511 and the second light-emitting element 512 in operation, achieving the normal display of the first display region A1.

It should be noted that the pixel drive circuit 52 corresponding to the first light-emitting element 511 means that the first light-emitting element 511 emits light under the drive of this pixel drive circuit 52. The pixel drive circuit 52 corresponding to the second light-emitting element 512 means that the second light-emitting element 512 emits light under the drive of this pixel drive circuit 52.

In some embodiments of the present disclosure, the pixel drive circuit 52 corresponding to the first light-emitting element 511 and/or the pixel drive circuit 52 corresponding to the second light-emitting element 512 can be arranged in a region other than the first display region A1. As shown in FIG. 2 and FIG. 8, the pixel drive circuit 52 corresponding to the first light-emitting element 511 and the pixel drive circuit 52 corresponding to the second light-emitting element 512 are both arranged in the second display region A2. Such configuration improves the light transmittance of the first display region A1.

The pixel drive circuit 52 corresponding to the first light-emitting element 511 and/or the pixel drive circuit 52 corresponding to the second light-emitting element 512 are arranged in the first display region A1.

In some embodiments of the present disclosure, as shown in FIG. 2 and FIG. 8, the first light-emitting element 511 and the second light-emitting element 512 are driven by different pixel drive circuits 52 respectively, that is, the pixel drive circuit 52 electrically connected to the first light-emitting element 511 is different from the pixel drive circuit 52 electrically connected to the second light-emitting element 512.

The first light-emitting element 511 and the second light-emitting element 512 are driven by a same pixel drive circuit 52, that is, the first light-emitting element 511 and the second light-emitting element 512 are connected to the same pixel drive circuit 52. Such configuration reduces the number of pixel drive circuits 52 disposed in the display panel and reduces the difficulty of the layout of pixel drive circuits 52. Moreover, when the pixel drive circuit 52 electrically connected to the first light-emitting element 511 and the second light-emitting element 512 is disposed in the first display region A1, such configuration can reduce the number of pixel drive circuits 52 in the first display region A1, thereby improving the light transmittance of the first display region A1. In some embodiments, the light-emitting colors of the first light-emitting element 511 and the second light-emitting element 512 that are electrically connected to a same pixel drive circuit 52 can be the same to ensure the accuracy of the display color.

As shown in FIG. 9, the display panel further includes a fourth via 711 and a fifth via 712. The fourth via 711 runs through the second insulation sub-layer 412, and the fifth via 712 runs through the fourth insulation sub-layer 422. The fourth via 711 is configured to electrically connect the first connection line 61 and a first transferring line 710, and the fifth via 712 is configured to electrically connect the first transferring line 710 and the first electrode 71 of the corresponding first light-emitting element 511. As shown in FIG. 9, along the first direction h1, the fourth via 711 and the fifth via 712 both at least partially overlap with the first non-hollowed portion 212. When the initial conductive layer 2′ is irradiated by laser rays, the laser rays will be converged after passing through the fourth via 711 and the fifth via 712, so that the laser energy at the corresponding positions of the fourth via 711 and the fifth via 712 is different from the laser energy at other positions. Along the first direction h1, the fourth via 711 and the fifth via 712 at least partially overlap with the first non-hollowed portion 212, that is, the fourth via 711 and the fifth via 712 is disposed to correspond to the region required to be retained in the initial conductive layer 2′. In this way, in the process of irradiating the initial conductive layer 2′ by laser rays to form the first conductive layer 21, the laser rays will not pass through the fourth via 711 and the fifth via 712 to irradiate the portion corresponding to the light transmission region A11 in the initial conductive layer 2′. Therefore, it can avoid the problem of uneven etching caused by the difference between the energy of laser ray passing through the fourth via 711 and the fifth via 712 and the energy of laser ray at other positions in the light-transmitting region A11, which improves the uniformity of etching at each position in the light-transmitting region A11. In some embodiments of the present disclosure, as shown in FIG. 9, the first transferring line 710 and the second conductive portion 32 are disposed in a same layer.

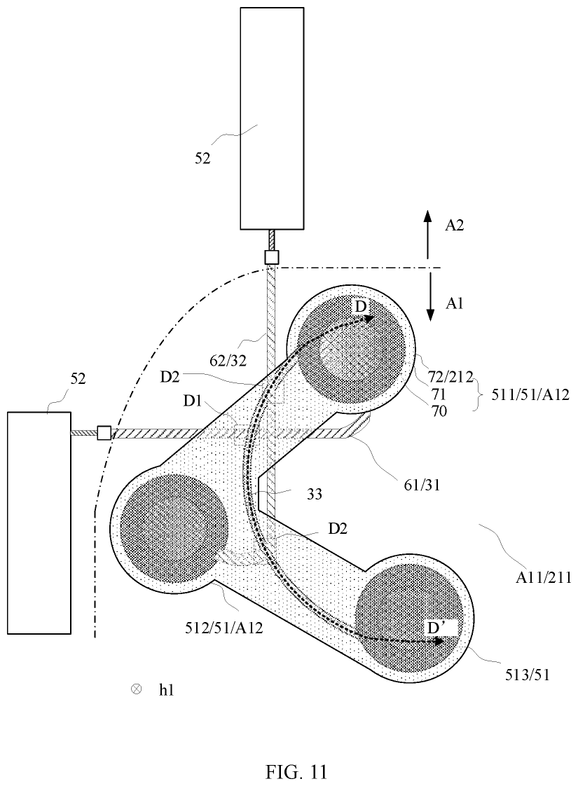

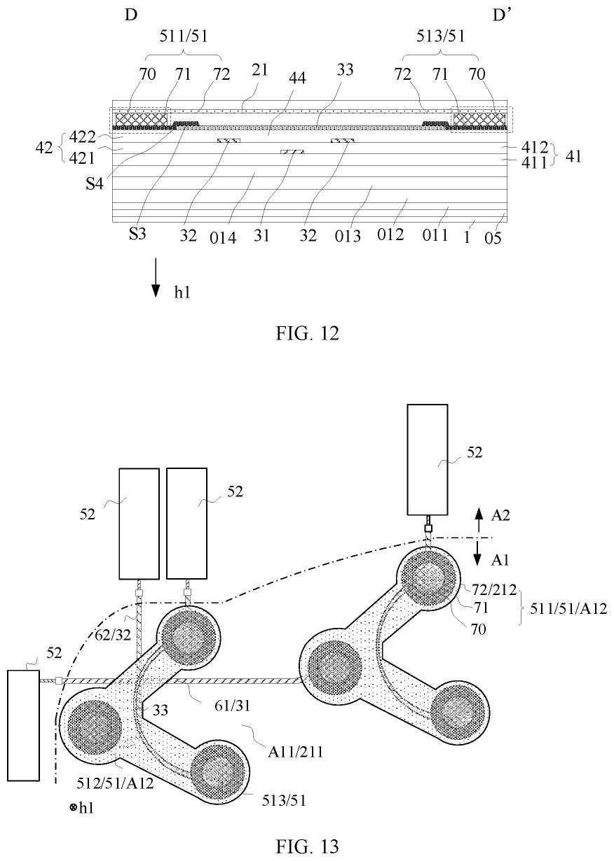

FIG. 11 is a partial enlarged diagram of a display panel according to another embodiment of the present disclosure, and FIG. 12 is a cross-sectional view taken along line DD′ of FIG. 11. In some embodiments of the present disclosure, as shown in FIG. 2, FIG. 11 and FIG. 12, multiple light-emitting elements 51 further include a third light-emitting element 513 having a same light-emitting color as the first light-emitting element 511. As shown in FIG. 11, the third light-emitting element 513 is electrically connected to the corresponding pixel drive circuit 52 through the first connection line 61 and a third conductive portion 33. The pixel drive circuit 52 corresponding to the third light-emitting element 513 means that the third light-emitting element 513 emits light under the drive of the pixel drive circuit 52. In some embodiments of the present disclosure, by electrically connecting the third light-emitting element 513 and the first light-emitting element 511 that have the same light-emitting color, one pixel drive circuit 52 can be used to drive both the first light-emitting element 511 and the third light-emitting element 513 when the display panel is operating, that is, the pixel drive circuit 52 corresponding to the third light-emitting element 513 and the pixel drive circuit 52 corresponding to the first light-emitting element 511 can be the same, so the number of the pixel drive circuit 52 in the display panel and the difficulty of the layout of the pixel drive circuit 52 are reduced.

In some embodiments of the present disclosure, as shown in FIG. 11, one end of the first connection line 61 can be electrically connected to a corresponding pixel drive circuit 52, the other end of the first connection line 61 can be electrically connected to the first light-emitting element 511. One end of the third conductive portion 33 can be electrically connected to the first light-emitting element 511, and the other end can be electrically connected to the third light-emitting element 513.

FIG. 11 just schematically shows that the pixel drive circuit 52 electrically connected to the third light-emitting element 513 and the first light-emitting element 511 is disposed in the second display region A2. In some embodiments of the present disclosure, the pixel drive circuit 52 electrically connected to the third light-emitting element 513 and the first light-emitting element 511 can also be disposed in the first display region A1. When the pixel drive circuit 52 electrically connected to the third light-emitting element 513 and the first light-emitting element 511 is disposed in the first display region A1, such configuration can reduce the number of pixel drive circuit 52 in the first display region A1, which improves the light transmittance of the first display region A1.

In some embodiments of the present disclosure, as shown in FIG. 12, the third conductive portion 33 is disposed in a different layer from the first conductive portion 31, and the third conductive portion 33 is disposed in a different layer from the second conductive portion 32. FIG. 12 schematically shows that the third conductive portion 33 is disposed on a side of the second conductive portion 32 away from the first conductive portion 31.

In some embodiments of the present disclosure, at least one of the first conductive portion 31 and the second conductive portion 32 may overlap with the third conductive portion 33 along the first direction h1. Such configuration can have a more compact arrangement of the third conductive portion 33 with the first conductive portion 31 and/or the second conductive portion 32, therefore avoiding problems with increased length caused by arranging the third conductive portion 33 away from the first conductive portion 31 or the second conductive portion 32. FIG. 12 schematically shows that the third conductive portion 33 overlaps with the first conductive portion 31 and the second conductive portion 32, respectively.

In some embodiments of the present disclosure, as shown in FIG. 11, along the first direction h1, the overlapping portion of the first conductive portion 31 and the third conductive portion 33 is a first overlapping portion D1, and the first overlapping portion D1 overlaps with the first non-hollowed portion 212 in the first direction h1. And/or, along the first direction h1, an overlapping portion of the second conductive portion 32 and the third conductive portion 33 is a second overlapping portion D2, and the second overlapping portion D2 overlaps with the first non-hollowed portion 212 in the first direction h1. With such configuration, in the process of irradiating the initial conductive layer 2′ by laser rays to form the first conductive layer 21, the laser ray will not be pass through the first overlapping portion D1 and/or the second overlapping portion D2 to irradiate the portion corresponding to the light transmission region A11 in the initial conductive layer 2′. Therefore, it can avoid the situation that the laser rays with more energy attenuation after passing through the first overlapping portion D1 and/or the second overlapping portion D2 cannot completely etch the portion corresponding to the light transmission region A11 in the initial conductive layer 2′, and then it can avoid occurrence of the residual foreign matter in the light transmission region A11, which can ensure the light transmittance of the first hollowed portion part 211. FIG. 11 schematically shows that the third conductive portion 33 overlaps with the first conductive portion 31 and the second conductive portion 32, respectively, and the second conductive portion 32 overlaps with the third conductive portion 33, to form two second overlapping portions D2.

FIG. 13 is a partial enlarged diagram of a display panel according to another embodiment of the present disclosure. In some embodiments of the present disclosure, as shown in FIG. 13, along the first direction h1, the first conductive portion 31, the second conductive portion 32, and the third conductive portion 33 have an overlapping, in other words, the first overlapping portion D1 can overlap with the second overlapping portion D2 in the first direction h1. Along the first direction h1, the overlapping portion of the first conductive portion 31, the second conductive portion 32 and the third conductive portion 33 overlaps with the first non-hollowed portion 212.

The first transistor T1 and/or the third transistor T3 in the pixel drive circuit shown in FIG. 6 may include an oxide transistor to reduce leakage current and improve the stability of the gate potential of the drive transistor T0. In some embodiments of the present disclosure, at least one of the first conductive portion 31, the second conductive portion 32, the third conductive portion 33, the fourth conductive portion 34 and the fifth conductive portion 35 can be located in a same layer as the semiconductor layer of the oxide transistor, and at least one of the first conductive portion 31, the second conductive portion 32, the third conductive portion 33, the fourth conductive portion 34 and the fifth conductive portion 35 is formed by a same patterning process as the semiconductor layer of the oxide transistor to simplify the manufacturing process of the display panel.

In some embodiments of the present disclosure, as shown in FIG. 12, the first light-emitting element 511 includes a first electrode 71, and the third conductive portion 33 may be disposed in a same layer as the first electrode 71. The expression “disposed in a same layer” means that there is no insulation layer between the third conductive portion 33 and the first electrode 71 in the first direction h1, and the third conductive portion 33 and the first electrode 71 are located on the surface of the fourth insulation layer 44. The fourth insulation layer 44 is located at a side of the third conductive portion 33 and the first electrode 71 close to the substrate 1. In some embodiments of the present disclosure, the third conductive portion 33 is in contact with the first electrode 71. Such configuration eliminates the need to dispose an insulation layer between the third conductive portion 33 and the first electrode 71, which reduces the number of layers in the display panel, reduces the thickness of the display panel, and simplifies the manufacturing process of the display panel.

As shown in FIG. 12, the third conductive portion 33 is disposed in a same layer as the first electrode 71 in the third light-emitting element 513. The meaning of “disposed in a same layer” is similar to that in “the third conductive portion 33 is disposed in a same layer as the first electrode 71 in the first light-emitting element 511”, which will not be elaborated here.

In some embodiments of the present disclosure, as shown in FIG. 12, at least part of the first electrode 71 may be located at a side of the third conductive portion 33 away from the substrate 1. In the manufacturing of the display panel, the third conductive portion 33 may be firstly formed, and then a first electrode 71 is formed. The first electrode 71 can at least partially wrap around the end of the third conductive portion 33 to increase the contact area between the first electrode 71 and the third conductive portion 33 and reduce the voltage drop of the signal transmitted between the first electrode 71 and the third conductive portion 33. The first electrode 71 of the first light-emitting element 511 at least partially wraps the end of the third conductive portion 33 close to the first light-emitting element 511, and the first electrode 71 of the third light-emitting element 513 at least partially wraps the end of the third conductive portion 33 close to the third light-emitting element 513.

In some embodiments of the present disclosure, as shown in FIG. 12, the end of the third conductive portion 33 includes a top surface S3 and multiple side surfaces S4, the top surface S3 is located at a side of the third conductive portion 33 away from the substrate 1, and the side surface S4 intersects with a plane of the substrate 1. In some embodiments of the present disclosure, the extension direction of some side surfaces S4 is parallel to the axial direction of the third conductive portion 33, and the extension direction of some side surfaces S4 is perpendicular to the axial direction of the third conductive portion 33. In some embodiments of the present disclosure, at least one of the top surface S3 and multiple side surfaces S4 is in contact with the first electrode 71.

In some embodiments of the present disclosure, the materials of the first electrode 71 and the third conductive portion 33 may be different. For example, the first electrode 71 can include metal, and the third conductive portion 33 can include a metal oxide.

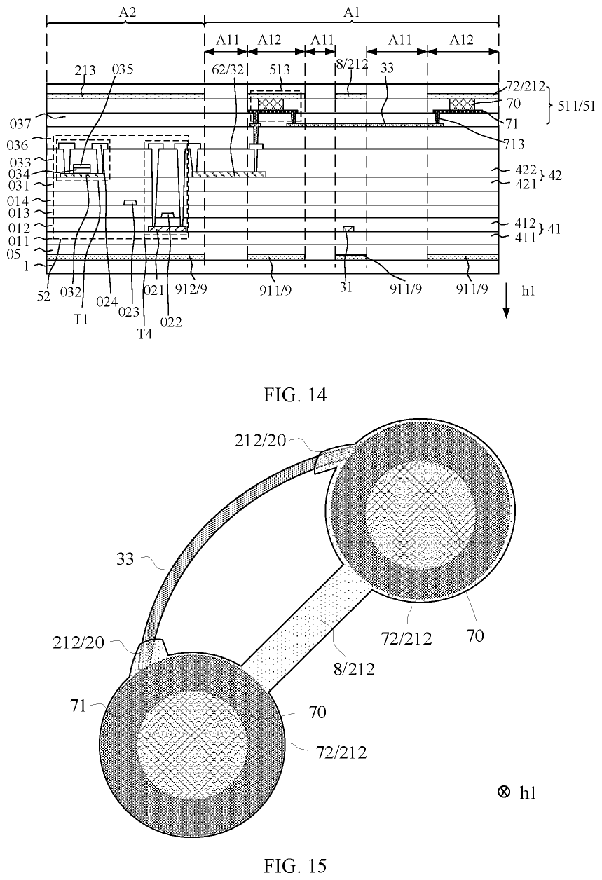

FIG. 14 is a cross-sectional diagram of a display panel according to another embodiment of the present disclosure. Alternatively, as shown in FIG. 14, the first transistor T1 in the pixel drive circuit 52 includes an oxide transistor, and the fourth transistor T4 includes a low-temperature polycrystalline silicon transistor.

As shown in FIG. 14, compared with FIG. 9, in some embodiments of the present disclosure, a sixth array insulation layer 031, a second semiconductor layer 032, a seventh array insulation layer 033, an eighth array insulation layer 034, and a fourth metal layer 035 may be arranged between the fourth array insulation layer 014 and the third metal layer 024. The second semiconductor layer 032 includes a channel of the first transistor T1. The fourth metal layer 035 includes a gate electrode the first transistor T1.

As shown in FIG. 14, in some embodiments of the present disclosure, the first conductive portion 31 and the channel of the fourth transistor T4 may be disposed in a same layer, i.e., disposed in the first semiconductor layer 021, and the first conductive portion 31 and the channel of the fourth transistor T4 may be formed by a same patterning process. The second conductive portion 32 and the channel of the first transistor T1 may be disposed in a same layer, i.e., disposed in the second semiconductor layer 032, and the second conductive portion 32 and the channel of the first transistor T1 may be formed by a same patterning process. The third conductive portion 33 is located between the third metal layer 024 and the first electrode 71. In some embodiments of the present disclosure, as shown in FIG. 14, along the first direction h1, the overlapping portion of the first conductive portion 31 and the third conductive portion 33 at least partially overlaps with the electrode connecting portion 8.

The first electrode 71 may include a light transmission electrode. The light transmittance of the light transmission electrode is greater than or equal to a second preset value, so that light can pass through the light transmission electrode smoothly. The second preset value can be set according to the photosensitive type, sensitivity, application scenario of the photosensitive element or other conditions of the photosensitive element. In some embodiments of the present disclosure, at least part of the light transmission electrode may extend to the light-transmitting region A11. In such a case, at least one of the first conductive portion 31 or the second conductive portion 32 includes the light transmission electrode. Such configuration can avoid that the laser ray passes through an interface between the light transmission electrode and the insulation layer or other structure in contact with the light transmission electrode and thus avoid occurrence of the residual foreign matter in the light transmission region A11.

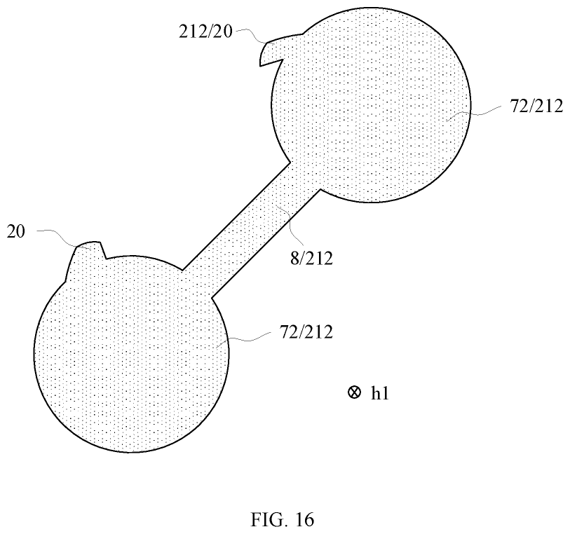

FIG. 15 is a partial enlarged diagram of a display panel according to another embodiment of the present disclosure, and FIG. 16 is a schematic diagram of a first conductive layer in FIG. 15. Alternatively, as shown in FIG. 15 and FIG. 16, the first non-hollowed portion 212 includes a protruding portion protruding from an edge of the first non-hollowed portion 212. Along the first direction h1, the overlapping portion of the first electrode 71 and the third conductive portion 33 at least partially overlaps with the protruding portion 20. If the difference between materials of the first electrode 71 and the third conductive portion 33 is large, in the process of etching the initial conductive layer 2′ by laser ray to form the first conductive layer 21 having the first hollowed portion 211, the overlapping portion of the first electrode 71 and the third conductive portion 33 will attenuate the energy of laser ray passing through it. In some embodiments of the present disclosure, the protruding portion 20 is disposed, the overlapping portion of the first electrode 71 and the third conductive portion 33 at least partially overlaps with the protruding portion 20 in the first direction h1. That is, the overlapping portion of the first electrode 71 and the third conductive portion 33 is disposed by corresponding to the region to be retained in the initial conductive layer 2′. In this way, in the process of irradiating the initial conductive layer 2′ by laser ray to form the first conductive layer 21, the laser ray will not pass through the overlapping portion of the first electrode 71 and the third conductive portion 33 to irradiate the portion corresponding to the light transmission region A11 in the initial conductive layer 2′. Therefore, it can avoid the situation that the laser ray with more energy attenuation after passing through the first electrode 71 and the third conductive portion 33 cannot completely etch the portion corresponding to the light transmission region A11 in the initial conductive layer 2′, and then it can avoid occurrence of the residual foreign matter in the light transmission region A11.

In some embodiments of the present disclosure, the area of the orthographic projection of the protruding portion 20 on the plane of the substrate 1 is smaller than that of at least one of the second electrode 72 and the electrode connecting portion 8. With such configuration, the area of the first non-hollowed portion 212 is reduced while avoiding residual foreign matter, and the light transmittance of the first display region A1 can be further increased. In some embodiments of the present disclosure, in at least one direction parallel to the plane of substrate 1, the width of the protruding portion 20 can be smaller than the width of at least one of the second electrode 72 and the electrode connecting portion 8 in the same direction.

In some embodiments of the present disclosure, the orthographic projection of at least one of the first conductive portions 31, the second conductive portions 32, and the third conductive portions 33 on the substrate 1 includes an arc to improve or eliminate the diffraction phenomenon of light or ray passing through the first display region AA.

In some embodiments of the present disclosure, as shown in FIG. 3, at the overlapping portion of the first conductive portion 31 and the second conductive portion 32, an angle α is formed between the first conductive portion 31 and the second conductive portion 32, where 60°≤a≤90°. Such configuration can reduce the area of the overlapping portion of the first conductive portion 31 and the second conductive portion 32, and can reduce the radiation range of the affected laser ray when the laser ray irradiates the overlapping portion of the first conductive portion 31 and the second conductive portion 32.

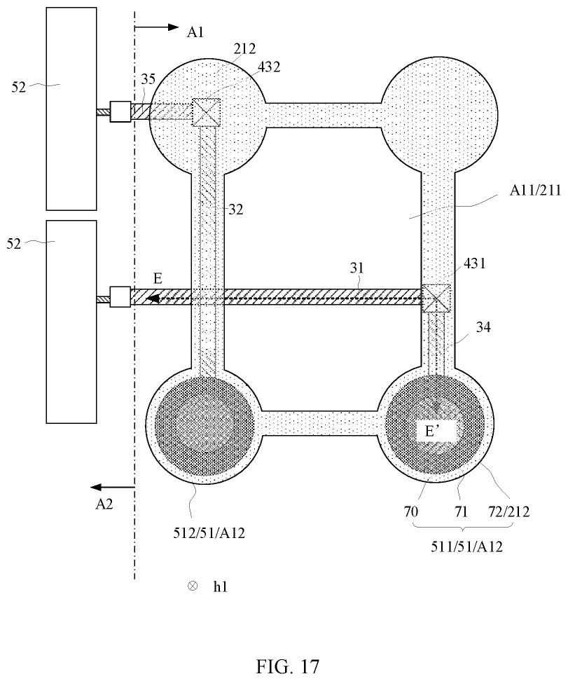

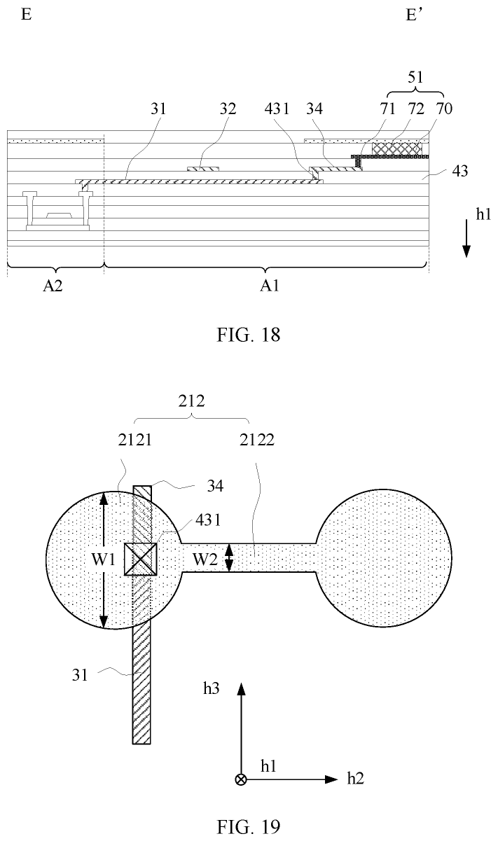

FIG. 17 is a partial enlarged diagram of a display panel according to another embodiment of the present disclosure, and FIG. 18 is a cross-sectional view taken along line EE′ in FIG. 17. In some embodiments of the present disclosure, as shown in FIG. 17 and FIG. 18, the first display region A1 includes a fourth conductive portion 34. As shown in FIG. 18, along the first direction h1, a third insulation layer 43 is located between the fourth conductive portion 34 and the first conductive portion 31. The third insulation layer 43 includes a first via 431. The first conductive portion 31 and the fourth conductive portion 34 are electrically connected through the first via 431. As shown in FIG. 17 and FIG. 18, along the first direction h1, the first via 431 at least partially overlaps with the first non-hollowed portion 212.

When the initial conductive layer 2′ is irradiated by laser ray, the laser ray will be converged after passing through the first via 431, so that the laser energy at the corresponding position of the first via 431 is different from the laser energy at other positions. Along the first direction h1, the first via 431 at least partially overlaps with the first non-hollowed portion 212, that is, the first via 431 is disposed to correspond to the region required to be retained in the initial conductive layer 2′. In this way, in the process of irradiating the initial conductive layer 2′ by laser ray to form the first conductive layer 21, the laser ray will not pass through the first via 431 and irradiate the portion corresponding to the light transmission region A11 in the initial conductive layer 2′. Therefore, it can avoid the problem of uneven etching caused by the difference between the energy of laser ray passing through the first via 431 and the energy of laser ray at other positions in the light-transmitting region A11, which improves the uniformity of etching at each position in the light-transmitting region A11.

As shown in FIG. 17, the first display region A1 further includes a fifth conductive portion 35 electrically connected to the second conductive portion 32 through the second via 432. Along the first direction h1, the second via 432 at least partially overlaps with the first non-hollowed portion 212.

In some embodiments of the present disclosure, as shown in FIG. 18, the fourth conductive portion 34 and the second conductive portion 32 may be disposed in a same layer.

In some embodiments of the present disclosure, as shown in FIG. 17, the extension direction of the first conductive portion 31 and the extension direction of the fourth conductive portion 34 may intersect each other. FIG. 19 is a partial enlarged diagram of a display panel according to another embodiment of the present disclosure. Alternatively, as shown in FIG. 19, the extension direction of the first conductive portion 31 and the extension direction of the fourth conductive portion 34 may be parallel to each other.

In some embodiments, as shown in FIG. 19, the first non-hollowed portion 212 includes a first sub-portion 2121 and a second sub-portion 2122 arranged along the second direction h2. The width W1 of the first sub-portion 2121 in the third direction h3 is greater than the width W2 of the second sub-portion 2122 in the third direction h3. The orthographic projection of the first sub-portion 2121 on the substrate 1 covers the orthographic projection of the first via 431 on the substrate 1. The third direction h3 is parallel to the plane of the substrate 1, and the second direction h2 intersects with the third direction h3. FIG. 19 schematically shows that the second direction h2 is perpendicular to the third direction h3. In some embodiments of the present disclosure, the first sub-portion 2121 and the second sub-portion 2122 may be disposed adjacent to each other. As shown in FIG. 17, the first sub-portion 2121 and the second sub-portion 2122 may be in contact with each other. In some embodiments of the present disclosure, the first via 431 is disposed by corresponding to the first sub-portion 2121 with a larger width in the first non-hollowed portion 212, the first sub-portion 2121 can be configured to fully shield the first via 431. When the first via 431 is slightly displaced or deformed in the third direction h3 due to process deviation, such configuration can ensure that the laser ray will not irradiate the first via 431.

For multiple directions parallel to the plane of substrate 1, the width of the first sub-portion 2121 is set to be greater than the width of the second sub-portion 2122 in the same direction, so that the area of the orthographic projection of the first sub-portion 2121 in the plane of the substrate 1 is greater than the area of the orthographic projection of the second sub-portion 2122 on the plane of the substrate 1. FIG. 19 schematically shows that the shape of the orthographic projection of the first sub-portion 2121 on the plane of the substrate is approximate circular, and the shape of the orthographic projection of the second sub-portion 2122 on the plane of the substrate is elongated. In an embodiment of the present disclosure, along multiple directions parallel to the plane of the substrate except the extension direction of the second sub-portion 2122, the width of the first sub-portion 2121 may be greater than the width of the second sub-portion 2122.

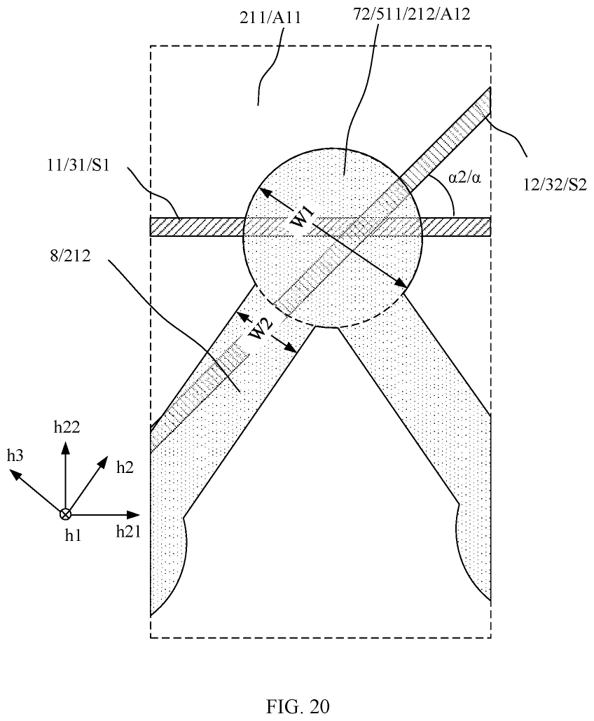

Multiple pairs of the first conductive portions 31 and the second conductive portions 32 with different included angles can be disposed in the display region A1. FIG. 20 is a partial enlarged diagram of a first display region of a display panel according to another embodiment of the present disclosure. As shown in FIG. 3, an angle α1 is formed between the first conductive portion 31 and the second conductive portion 32. As shown in FIG. 20, an angle α2 is formed between the first conductive portion 31 and the second conductive portion 32, where α1>α2. Accordingly, the overlapping area of the first conductive portion 31 and the second conductive portion 32 in FIG. 3 is smaller than the overlapping area of the first conductive portion 31 and the second conductive portion 32 in FIG. 20. In some embodiments of the present disclosure, as shown in FIG. 3 and FIG. 20, the first non-hollowed portion 212 includes the first sub-portion 2121 and the second sub-portion 2122 that are arranged along the second direction h2. The width W1 of the first sub-portion 2121 in the third direction h3 is greater than the width W2 of the second sub-portion 2122 in the third direction h3. As shown in FIG. 3, the orthographic projection of the second sub-portion 2122 with a smaller width on the substrate 1 can cover the overlapping portion of the first conductive portion 31 and the second conductive portion 32 that have a larger included angle. As shown in FIG. 20, the orthographic projection of the second sub-portion 2122 with a larger width on the substrate 1 can cover the overlapping portion of the first conductive portion 31 and the second conductive portion 32 that have a smaller included angle.

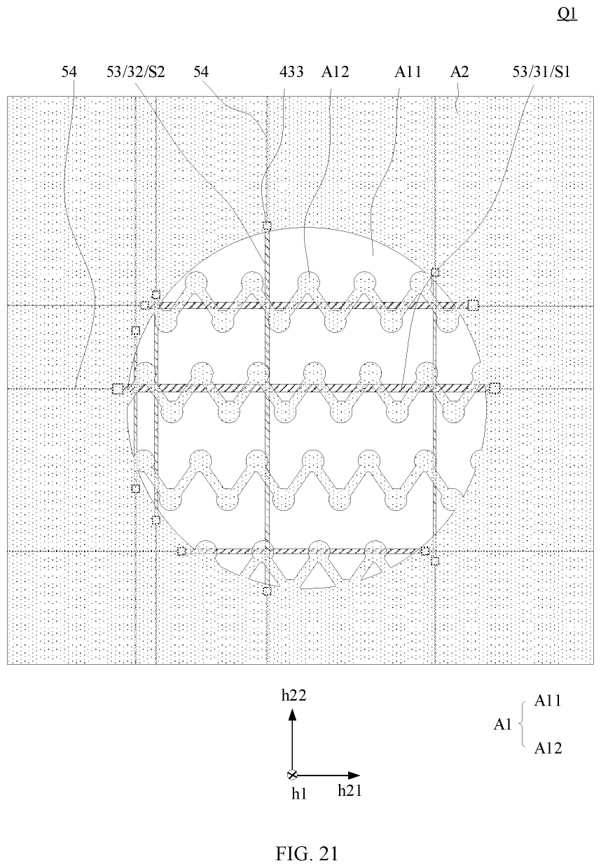

FIG. 21 is an enlarged diagram of a region Q1 in FIG. 1. In some embodiments of the present disclosure, the first display region A1 includes a first signal line 53. The first signal line 53 includes a light transmission portion, and the light transmittance of light transmission portion is greater than or equal to the second preset value, so that light can pass the light transmission portion smoothly. In some embodiments of the present disclosure, at least one of the first conductive portion 31 and the second conductive portion 32 includes the light transmission portion. FIG. 21 schematically shows that two first signal lines 53 with different extension directions in the first display region A1. The light transmission portion of one of the two first signal lines 53 is the first conductive portion 31, and the light transmission portion of the other of the two first signal lines 53 is the second conductive portion 32. In addition, one of the two first signal lines 53 extends along the fourth direction h21, and the other of the two first signal lines 53 extends along the fifth direction h22.

In some embodiments of the present disclosure, referring to FIG. 6, the display panel further includes a scan line, a light-emitting control signal line E, a reset signal line Ref, a data line Data, and a first power line PVDD. The scan line includes a first scan line S1 and a second scan line S2. In some embodiments of the present disclosure, the first signal line 53 includes at least one of the first scan line S1, the second scan line S2, the light-emitting control signal line E, the reset signal line Ref, the data line Data, and the first power line PVDD.

In some embodiments of the present disclosure, as shown in FIG. 21, the second display region A2 includes a second signal line 54. The second signal line 54 and the first signal line 53 are arranged at different layers. The second signal line 54 and the corresponding first signal line 53 are electrically connected through the third via 433. In some embodiments of the present disclosure, the second signal line 54 includes a metal material, and the first signal line 53 includes a metal oxide.

In some embodiments of the present disclosure, the second signal line 54 includes at least one of the scan line, the light-emitting control signal line E, the reset signal line Ref, the data line Data and the first power line PVDD. In some embodiments of the present disclosure, the second signal line 54 is disposed by avoiding the first display region A1, so that the light transmittance of the first display region A1 can be improved. Furthermore, based on the above configuration in the embodiments of the present disclosure, the first signal line 53 is connected to two second signal lines 54 located on two sides of the first display region A1 in the extension direction of the second signal line 54, in other words, the first signal line 53 is electrically connected to the second signal line 54 cut off by the first display region A1. When the second signal line 54 is electrically connected to the pixel drive circuit 52, it is ensured that the pixel drive circuits 52 located on two sides of the first display region A1 can normally receive the corresponding display signals, ensuring the normal drive of the pixel drive circuits 52.

In some embodiments of the present disclosure, as shown in FIG. 21, the display panel includes multiple second signal lines 53 extending along the fourth direction h21. The width of the second signal line 53 extending along the fourth direction h21 with a greater length is smaller than that of the second signal line 53 extending along the fourth direction h21 with a smaller length, so that the loads of multiple second signal lines 53 extending along the fourth direction h21 tend to be consistent.

Moreover, as shown in FIG. 21, the display panel includes multiple second signal lines 53 extending along the fifth direction h22. The width of the second signal line 53 extending along the fifth direction h22 with a greater length is smaller than that of the second signal line 53 extending along the fifth direction h22 with a smaller length, so that the loads of multiple second signal lines 53 extending along the fifth direction h22 tend to be consistent.

It should be noted that as shown in FIG. 21, the second signal lines 54 extending in different directions are disposed in different layers.

In some embodiments of the present disclosure, the first conductive portion 31, the second conductive portion 32, the third conductive portion 33, the fourth conductive portion 34 and the fifth conductive portion 35 include a metal oxide. In some embodiments, the metal oxide includes one or more of Indium Tin Oxide (ITO), Indium Zinc Oxide (IZO), Indium Gallium Zinc Oxide (IGZO).

In some embodiments of the present disclosure, two overlapping ones of the first conductive portion 31, the second conductive portion 32, the third conductive portion 33, the fourth conductive portion 34, and the fifth conductive portion 35 includes a same material or different materials.

When two overlapping ones of the first conductive portion 31, the second conductive portion 32, the third conductive portion 33, the fourth conductive portion 34, and the fifth conductive portion 35 include different materials, referring to FIG. 19, in the first direction h1, the overlapping portion of the two overlapping ones at least partially overlaps with the first sub-portion 2121 having a larger width. When the two overlapping ones include different materials, the laser ray has a relatively large energy loss after passing through the overlapping portion of two conductive portions with different materials. In some embodiments of the present disclosure, the overlapping portion of two conductive portions with different materials overlaps with the first sub-portion 2121, so that the first sub-portion 2121 can fully shield the overlapping portion of two conductive portions with different materials. When the overlapping portion of two conductive portions with different materials is slightly displaced or deformed in the third direction h3 due to process deviation, such configuration can ensure that the laser ray will not irradiate the overlapping portion.

In some embodiments of the present disclosure, the first sub-portion 2121 overlapping the overlapping portion of two conductive portions with different materials in the first direction h1 includes any of the second electrode 72, the electrode connecting portion 8, and the protruding portion 20.

The first transistor T1 and the third transistor T3 in the pixel drive circuit shown in FIG. 6 may include an oxide transistor to reduce the leakage current and improve the stability of gate potential of the drive transistor T0. In some embodiments of the present disclosure, at least one of the first conductive portion 31, the second conductive portion 32, the third conductive portion 33, the fourth conductive portion 34 and the fifth conductive portion 35 can be disposed in a same layer as the semiconductor layer of the oxide transistor. At least one of the first conductive portion 31, the second conductive portion 32, the third conductive portion 33, the fourth conductive portion 34 and the fifth conductive portion 35 are formed by a same patterning process as the semiconductor layer of the oxide transistor to simplify the manufacturing process of the display panel.

In some embodiments of the present disclosure, as shown in FIG. 2, the extension directions of two adjacent electrode connecting portion 8 intersect with each other, and/or the shape of the edge of the electrode connecting portion 8 includes arcs or polylines, and/or the shape of the edge of the second electrode 72 in the first display region A1 includes arcs or polylines. With such configuration, the patterns of the first conductive layers 21 in the first display region A1 tend to be irregularly distributed, which weakens the diffraction problem of the first display region A1.

The present disclosure further provides a method for manufacturing a display panel. Referring to FIG. 4, the method includes following steps.

Step S1: the substrate 1 is provided, and the substrate 1 includes the first display region A1.

Step S2: the first blocking portion 11 at least located in the first display region A1 is formed at a side of substrate 1.

Step S3: the second blocking portion 12 at least located in the first display region A1 is formed on a side of the first blocking portion 11 away from the substrate 1, and, in the first direction h1, the second blocking portion 12 and the first blocking portion 11 at least partially overlap. The first direction h1 is perpendicular to a plane of the substrate 1. The first display region A1 includes the first region A11 and the second region A12. Along the first direction h1, the second region A12 at least partially overlaps with the overlapping portion of the second blocking portion 12 and the first blocking portion 11.

Step S4: an initial conductive layer 2′ at least located in the first display region A1 is formed at a side of the second blocking portion 12 away from the first blocking portion 11.

Step S5: at least part of the initial conductive layer 2′ located in the first region A11 is removed to form a first conductive layer 21, the first conductive layer 21 includes the first hollowed portion 21 at least partially located in the first region A11 and the first non-hollowed portion 212 at least partially located in the second region A12, so that the overlapping portion of the first blocking portion 11 and the second blocking portion 12 at least partially overlaps with the first non-hollowed portion 212 in the first direction h1. At least part of the first region A11 corresponds to the light-transmitting region A11, and at least part of the second region A12 corresponds to the light-emitting region A12.

In some embodiments of the present disclosure, the method for removing at least a portion of the initial conductive layer 2′ located in the first region A11 includes: etching the initial conductive layer 2′ by laser ray.

As shown in FIG. 4, the laser light irradiates the initial conductive layer 2′ from a side of the substrate 1 away from the first blocking portion 11.

In the method for manufacturing the display panel provided by the embodiments of the present disclosure, the overlapping portion of the first blocking portion 11 and the second blocking portion 12 at least partially overlaps with the second region A12 in the first direction h1, that is, the overlapping portion of the first blocking portion 11 and the second blocking portion 12 is disposed by corresponding to the region to be retained in the initial conductive layer 2′. In this way, in the process of irradiating the initial conductive layer 2′ by laser ray to form the first conductive layer 21, the laser ray will not pass through the overlapping portion of the first blocking portion 11 and the second blocking portion 12 and not irradiate the portion corresponding to the light transmission region A11 in the initial conductive layer 2′. Therefore, it can avoid the problem that the laser ray has energy attenuation after passing through the first blocking portion 11 and the second blocking portion 12, the laser ray having low energy due to attenuation cannot completely etch the portion corresponding to the light transmission region A11 in the initial conductive layer 2′, and then it can avoid occurrence of the residual foreign matter in the light transmission region A11. Moreover, the residual foreign matter will affect the light transmittance of the first conductive layer 21 in the light transmission region A11. Therefore, the embodiments of the present disclosure can ensure that the first hollowed portion 211 in the first conductive layer 21 has a sufficiently high light transmittance, so as to ensure the operating performance of the photosensitive element in the first display region A1.

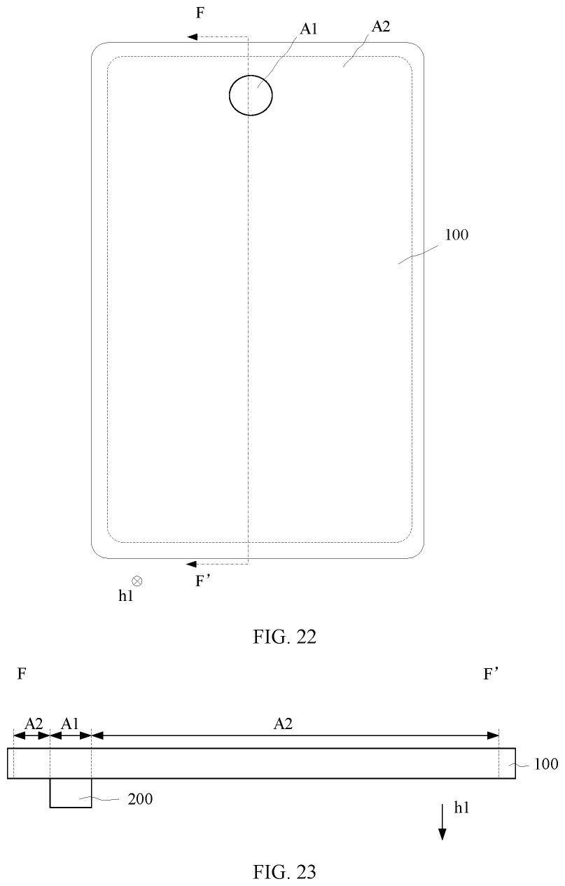

The present disclosure further provides a display apparatus. FIG. 22 is a schematic diagram of a display apparatus according to an embodiment of the present disclosure. As shown in FIG. 22, the display apparatus includes the display panel 100 mentioned above. The structure of the display panel 100 has been described in the above embodiments, and will not be repeated here. FIG. 22 just schematically shows the display apparatus. The display apparatus may be any electronic device with display function, such as a mobile phone, a tablet computer, a laptop computer, an electronic book or a television.

FIG. 23 is a cross-sectional view taken along line FF′ in FIG. 22. In some embodiments of the present disclosure, as shown in FIG. 23, the display apparatus further includes a photosensitive element 200 disposed in the first display region A1. When the photosensitive element 200 operates, the light in ambient environment can pass through the first display region A1 and be received by the photosensitive element 200. Such configuration can improve the light transmittance of the first display region A1, thus ensuring the operating performance of the photosensitive element 200.

The above are merely exemplary embodiments of the present disclosure, which, as mentioned above, are not configured to limit the present disclosure. Whatever within the principles of the present disclosure, including any modification, equivalent substitution, improvement, etc., shall fall into the protection scope of the present disclosure.

What is claimed is:

1. A display panel, comprising: a substrate and a first display region,
wherein the first display region comprises:
a light transmission region;
a first blocking portion located at a side of the substrate;
a second blocking portion located at a side of the first blocking portion away from the substrate; and
a first conductive layer located at a side of the second blocking portion away from the first blocking portion, wherein the first conductive layer comprises a first hollowed portion and a first non-hollowed portion, and the first hollowed portion is located in the light transmission region,
wherein, along a first direction, the first blocking portion at least partially overlaps with the second blocking portion, and an overlapping between the first blocking portion and the second blocking portion at least partially overlaps with the first non-hollowed portion, and the first direction is perpendicular to a plane of the substrate.

2. The display panel according to claim 1, wherein the first display region further comprises a first conductive portion and a second conductive portion,
wherein the display panel further comprises a first insulation layer at a side of the first conductive portion and a second insulation layer at a side of the second conductive portion,
the first blocking portion comprises a first interface between the first insulation layer and the first conductive portion, and
the second blocking portion comprises a second interface between the second insulation layer and the second conductive portion.

3. The display panel according to claim 2, wherein the first conductive portion at least partially overlaps with the second conductive portion along the first direction, or an extension direction of the first interface and an extension direction of the second interface intersect with each other.

4. The display panel according to claim 2, wherein,
the first insulation layer comprises a first insulation sub-layer and a second insulation sub-layer, and along the first direction, the first insulation sub-layer and the second insulation sub-layer are located on two sides of the first conductive portion respectively; and/or,
the second insulation layer comprises a third insulation sub-layer and a fourth insulation sub-layer, and along the first direction, the third insulation sub-layer and the fourth insulation sub-layer are located on two sides of the second conductive portion respectively.

5. The display panel according to claim 2, further comprising light-emitting elements and pixel drive circuits, wherein the pixel drive circuits are configured to drive the light-emitting elements to emit light,
the light-emitting elements comprise a first light-emitting element and a second light-emitting element that are located in the first display region,
the first light-emitting element is electrically connected to a pixel drive circuit of the pixel drive circuits through a first connection line, and the first connection line comprises the first conductive portion, and
the second light-emitting element is electrically connected to a pixel drive circuit of the pixel drive circuits through a second connection line, and the second connection line comprises the second conductive portion.

6. The display panel according to claim 5, wherein,
the first light-emitting element and the second light-emitting element have a same light-emitting color, and are electrically connected to a same pixel drive circuit of the pixel drive circuits; or,
the first light-emitting element and the second light-emitting element are electrically connected to different pixel drive circuits of the pixel drive circuits.

7. The display panel according to claim 5, wherein, the light-emitting elements further comprise a third light-emitting element, and the third light-emitting element has a same light-emitting color as the first light-emitting element, and
the third light-emitting element is electrically connected to a pixel drive circuit of the pixel drive circuits through the first connection line and a third conductive portion.

8. The display panel according to claim 7, wherein at least one of the first conductive portion or the second conductive portion overlaps with the third conductive portion along the first direction.

9. The display panel according to claim 8, wherein, along the first direction, an overlapping portion of the first conductive portion and the third conductive portion is a first overlapping portion, and the first overlapping portion overlaps with the first non-hollowed portion along the first direction; and/or,
along the first direction, an overlapping portion of the second conductive portion and the third conductive portion is a second overlapping portion, and the second overlapping portion overlaps with the first non-hollowed portion along the first direction.

10. The display panel according to claim 7, wherein the first light-emitting element comprises a first electrode arranged in a same layer as the third conductive portion, or at least one of the first, second or third conductive portions has an orthographic projection on the substrate comprising an arc.

11. The display panel according to claim 2, wherein an angle α formed between the first conductive portion and the second conductive portion satisfies 60°≤α≤90°.

12. The display panel according to claim 2, wherein the first display region further comprises a fourth conductive portion, and along the first direction, a third insulation layer is located between the fourth conductive portion and the first conductive portion, the third insulation layer comprises a first via through which the first conductive portion and the fourth conductive portion are electrically connected, and wherein the first via at least partially overlaps with the first non-hollowed portion.

13. The display panel according to claim 12, wherein the first non-hollowed portion comprises a first sub-portion and a second sub-portion that are arranged along a second direction, and a width in a third direction of the first sub-portion is greater than a width in the third direction of the second sub-portion,
an orthographic projection of the first sub-portion on the substrate covers an orthographic projection of the first via on the substrate, and
the third direction is parallel to the plane of the substrate, and the second direction intersects the third direction.

14. The display panel according to claim 2, wherein the first display region further comprises a first signal line comprising a light transmission portion, and at least one of the first conductive portion or the second conductive portion comprises the light transmission portion.

15. The display panel according to claim 2, wherein the first display region further comprises a light-emitting region comprising a first light-emitting element, the first light-emitting element comprises a first electrode, a light-emitting layer and a second electrode that are stacked, and the first non-hollowed portion comprises the second electrode,
the first electrode comprises a light transmission electrode, at least a portion of the light transmission electrode extends to the light transmission region, and
at least one of the first conductive portion or the second conductive portion comprises the light transmission electrode.

16. The display panel according to claim 1, wherein the first display region further comprises a first light-emitting element, the first light-emitting element comprises a first electrode, a light-emitting layer and a second electrode that are stacked, and the first non-hollowed portion comprises the second electrode.

17. The display panel according to claim 16, wherein the first display region comprises a plurality of light-emitting regions, the first non-hollowed portion further comprises an electrode connecting portion, and two adjacent second electrodes are electrically connected by the electrode connecting portion, and
along the first direction, an overlapping portion of the first blocking portion and the second blocking portion overlaps with the second electrode or the electrode connecting portion.

18. The display panel according to claim 1, further comprising a shielding layer, wherein the shielding layer is located a side of the first blocking portion close to the substrate, and comprises a second hollowed portion located in the light transmission region, and
along the first direction, the second hollowed portion at least partially overlaps with the first hollowed portion.

19. A method for manufacturing a display panel, comprising:
providing a substrate, wherein the substrate comprises a first display region;
forming a first blocking portion, wherein the first blocking portion is at a side of the substrate and at least located in the first display region;
forming a second blocking portion at a side of the first blocking portion away from the substrate, wherein the second blocking portion is at least located in the first display region, and at least partially overlaps with the first blocking portion in a first direction that is perpendicular to a plane of the substrate;
forming an initial conductive layer at a side of the second blocking portion away from the first blocking portion, wherein the initial conductive layer is at least located in the first display region, the first display region comprises a first region and a second region, along the first direction, the second region at least partially overlaps with an overlapping portion of the second blocking portion and the first blocking portion; and
removing at least a portion of the initial conductive layer located in the first region via etching the initial conductive layer by laser rays to form a first conductive layer, wherein the first conductive layer comprises a first hollowed portion at least partially located in the first region and a non-hollowed portion at least partially located in the second region, so that the overlapping portion of the first blocking portion and the second blocking portion at least partially overlaps with the first non-hollowed portion.

20. A display apparatus comprising a display panel, wherein the display panel comprises a substrate and a first display region,
wherein the first display region comprises:
a light transmission region;
a first blocking portion located at a side of the substrate;
a second blocking portion located at a side of the first blocking portion away from the substrate; and
a first conductive layer located at a side of the second blocking portion away from the first blocking portion, wherein the first conductive layer comprises a first hollowed portion and a first non-hollowed portion, and the first hollowed portion is located in the light transmission region,
wherein, along a first direction, the first blocking portion at least partially overlaps with the second blocking portion, and an overlapping between the first blocking portion and the second blocking portion at least partially overlaps with the first non-hollowed portion, and the first direction is perpendicular to a plane of the substrate.
